(19) United States
(12) Patent Application Publication
(10) Pub. No.: US 2024/0222335 A1
(43) Pub. Date: Jul. 4, 2024

(54) ELECTRONIC CONTROL UNIT, MANUFACTURING METHOD THEREOF, AND ELECTRIC COMPRESSOR

(71) Applicant: Robert Bosch GmbH, Stuttgart (DE)

(72) Inventors: Bo Liu, Suzhou (CN); Zhu Li, Suzhou (CN)

(21) Appl. No.: 18/399,871

(22) Filed: Dec. 29, 2023

(30) Foreign Application Priority Data
Dec. 29, 2022 (CN) 202211741628.8

(51) Int. Cl. H01L 25/07; H01L 21/48; H01L 23/00; H01L 23/40

(52) U.S. Cl. CPC H01L 25/072; H01L 21/4871; H01L 23/4006; H01L 24/32; H01L 24/40; H01L 24/73; H01L 24/84; H01L 2023/4068; H01L 2224/32221; H01L 2224/40225; H01L 2224/73263; H01L 2224/84801; H01L 2924/13055; H01L 2924/1616; H01L 2924/16235

(57) ABSTRACT

Provided in the present application are an electronic control unit, a manufacturing method thereof, and an electric compressor. The electronic control unit includes: a chip support, including a plurality of chip cavities, each of the chip cavities including a bottom wall; chips arranged in the chip cavities, each chip including: a support surface close to the bottom wall and a heat dissipation surface opposite the support surface, wherein the bottom wall of the chip cavity is provided with a plurality of support protrusions, and when the electronic control unit is completely assembled, the plurality of support protrusions are compressed and deform; and a heat sink, abutting and thermally contacting the heat dissipation surfaces of the plurality of chips. The device and method according to the embodiments of the present invention can ensure that a plurality of chips are all in good contact with a heat sink for heat dissipation.

### BACKGROUND

The present invention relates to the field of electronic control units, and more specifically, the present invention relates to an electronic control unit, a manufacturing method thereof, and an electric compressor.

For an electronic control unit (e.g., an electronic control unit of a vehicle-mounted electric compressor) having a plurality of IGBT chips, heat dissipation of each IGBT chip is very important. How to ensure good contact between the plurality of IGBT chips and a heat sink is a challenge.

### SUMMARY

An objective of the present application is to solve or at least alleviate the problem in the prior art.

In an aspect, provided is an electronic control unit, comprising:
a chip support, comprising a plurality of chip cavities, each of the chip cavities comprising a bottom wall;
chips arranged in the chip cavities, each chip comprising: a support surface close to the bottom wall and a heat dissipation surface opposite the support surface, wherein the bottom wall of the chip cavity is provided with a plurality of support protrusions, and when the electronic control unit is completely assembled, the plurality of support protrusions are compressed and deform; and
a heat sink, abutting and thermally contacting the heat dissipation surfaces of the plurality of chips.

Also provided is an electric compressor, comprising a compressor body; and the electronic control unit according to embodiments of the present invention, integrated on the compressor body.

In another aspect, provided is a manufacturing method of an electronic control unit, comprising:
mounting a plurality of chips in a plurality of chip cavities of a chip support, each of the chip cavities comprising a bottom wall, each chip comprising a support surface close to the bottom wall and a heat dissipation surface opposite the support surface, the bottom wall of the chip cavity comprising a plurality of support protrusions, the chip comprising a terminal, and the terminal passing through a through hole on the bottom wall of the chip cavity and extending to a back side of the chip support;
maintaining the chip support fixed, and performing compression from the heat dissipation surfaces of the plurality of chips by means of a flat indenter, so that the plurality of support protrusions in each of the chip cavities deform; and
soldering, on the back side of the chip support, the terminals of the plurality of chips to a circuit board, so that the heat dissipation surfaces of the plurality of chips are flush with each other.

The device and method according to the embodiments of the present invention can ensure that a plurality of chips are all in good contact with a heat sink for heat dissipation.

### BRIEF DESCRIPTION OF THE DRAWINGS

With reference to the accompanying drawings, the disclosure of the present application will become more comprehensible. It is comprehensible to those skilled in the art that these accompanying drawings are merely for the purposes of description, but are not intended to limit the scope of protection of the present application. In addition, similar numerals in the drawings are used to denote similar components, wherein:

FIG. 1 shows a perspective view of a chip support according to an embodiment;

FIG. 2 shows an enlarged view of a chip cavity of the chip support in FIG. 1;

FIG. 3 shows a sectional view when a chip support, a circuit board, and a heat sink are assembled according to an embodiment; and

FIG. 4 and FIG. 5 respectively show a perspective view and a sectional view of a support protrusion according to an embodiment.

### DETAILED DESCRIPTION

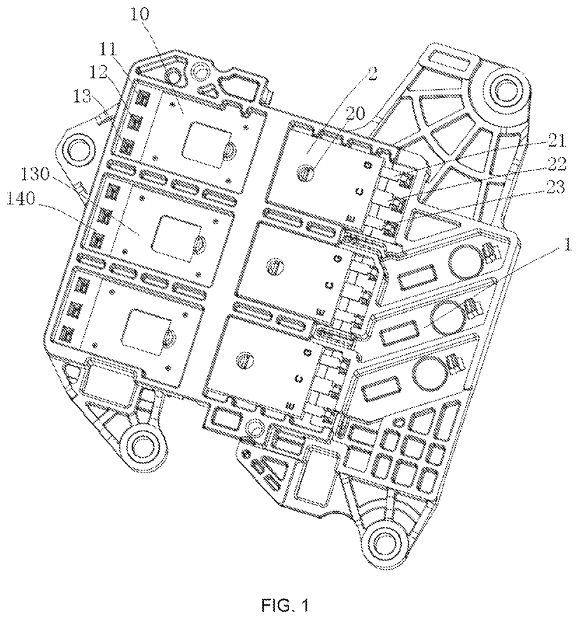

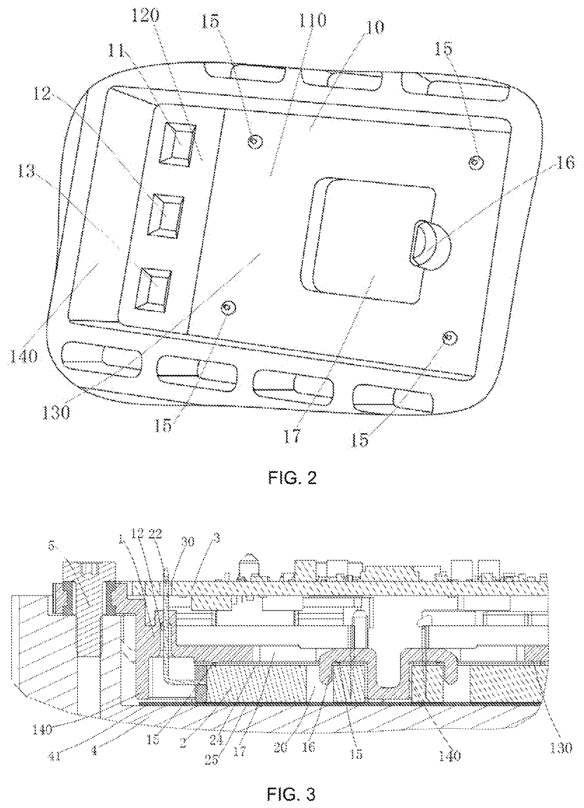

An electronic control unit according to an embodiment of the present invention is introduced with reference to FIG. 1 to FIG. 3. The electronic control unit includes a chip support 1 shown in FIG. 1 and FIG. 2. The chip support 1 includes a plurality of chip cavities 10. For example, the chip support 1 shown in FIG. 1 includes two rows of chip cavities 10, and each row includes three chip cavities 10. A chip cavity on a right side is provided with a chip 2, e.g., an IGBT chip. When operating, the chip has high power, and has high requirements on heat dissipation. As shown in FIG. 2, each chip cavity 10 includes a bottom wall 130 and a side wall 140. Alternatively, the chip cavities 10 may be separated from each other by position-limiting members such as ribs or the like. Optionally, each chip cavity 10 may be further divided into a support region 110 and a connecting region 120 on a side of the support region 110.

The plurality of chips 2 are arranged in the plurality of corresponding chip cavities of the chip support 1. Each chip 2 includes: a support surface 24 close to the bottom wall 130 and a heat dissipation surface 25 opposite the support surface 24 (shown in FIG. 3). The bottom wall 130 of the chip cavity includes a plurality of support protrusions 15. When the electronic control unit is completely assembled, the plurality of support protrusions 15 of the plurality of chip cavities are compressed and deform, so that the heat dissipation surfaces 25 of the plurality of chips are substantially flush with each other. The heat dissipation surfaces 25 of the plurality of chips further abut and thermally contact a heat sink 4, e.g., direct fitting or indirect fitting, that is, an optional electrically insulating and thermally conductive film 41 may be provided therebetween. In actual production, it cannot be ensured that the chips 2 have completely the same thickness, so that by providing the compressible support protrusions 15, it can be ensured, by means of compression steps, that the heat dissipation surfaces 25 of the plurality of chips are flush with each other so as to be in good contact with a contact surface of the heat sink to exchange heat. For example, the compression steps may include pre-mounting the chips 2 to the chip cavities 10, fixing the chip support 1 by means of a fixture, and causing a flat indenter to simultaneously contact and press the heat dissipation surfaces 25 of the chips to deform the plurality of support protrusions 15 in the chip cavities, thereby compensating for thickness differences between the chips 2 by means of the different amounts of deformation of the support protrusions 15 in the different chip cavities, so that the heat dissipation surfaces 25 of the chips 2 are substantially flush with each other.

In addition, the electronic control unit further includes a circuit board 3 on a back side of the chip support. The bottom wall of the chip cavity includes one or more through holes 11, 12, 13. Terminals 21, 22, 23 of the plurality of chips pass through the through holes 11, 12, 13 and extend to the back side of the chip support (see FIG. 3), and the terminals of the plurality of chips are soldered to the circuit board 3 after the plurality of support protrusions 15 of the plurality of chip cavities are compressed and deform, so that the heat dissipation surfaces 25 of the plurality of chips 2 are flush with each other. It should be understood that the size of the through hole 11, 12, 13 on the bottom wall of the chip cavity is slightly larger than that of the terminal 21, 22, 23 of the chip 2, so that when the chip 2 is pre-mounted in the chip cavity 10, the position of the chip 2 is not completely fixed yet, and clearances in X and Y directions are present. As shown in the drawings, the circuit board 3 includes an open hole 30 through which the terminal 21, 22, 23 is allowed to pass. The terminal and the circuit board 3 are soldered to each other, so that the position of the chip 2 in a Z direction (an up-down direction in FIG. 3) is fixed. In this way, the heat dissipation surfaces 25 of the plurality of chips 2 are flush with each other, and meanwhile, the positions of the chip 2 in the X and Y directions are fixed.

In another aspect, the chip support 1 and the circuit board 3 have a position-limiting feature or a fixed connection therebetween, and are therefore fixedly connected to each other. Alternatively, after the chip 2 is soldered to the circuit board 3, the chip support 1, the circuit board 3, and the chip 2 are fixed relative to each other, and the heat dissipation surfaces 25 of the plurality of chips 2 are located in substantially the same plane. Subsequently, the chip support 1 may be fastened to the heat sink 4 by means of a plurality of bolts 5 provided around the chip cavities, so that the heat dissipation surfaces of the plurality of chips substantially in the same plane transfer heat to the heat sink 4, thereby ensuring that heat dissipation can be well performed on each chip.

In one embodiment, each chip cavity 20 is in the shape of a flat rectangle, and includes a support region 110 for supporting the chip and a connecting region 120 on a side of the support region. The connecting region 120 provides the through holes 11, 12, 13. In the support region 110, the support protrusion 15 is provided at each of four corners of the bottom wall 130, and a middle portion of the bottom wall is provided a position-limiting protruding portion 16 and a middle open hole 17. The position-limiting protruding portion 16 mates with a notch 20 of the chip 2, so as to preliminarily limit the position of the chip in the chip cavity, thereby preliminarily limiting the positions of the chip in the X direction and the Y direction (clearances are present). In the embodiment shown, the position-limiting protruding portion 16 is in the shape of a semi-circular column, and the notch 20 of the chip 2 is in the shape of a circular through hole passing through the chip 2.

Referring to FIG. 3, in some embodiments, after the plurality of support protrusions 15 are compressed, the heat dissipation surfaces 25 of the plurality of chips protrude from the side walls of the chip cavities, so that the heat dissipation surfaces of the plurality of chips have a higher priority of contacting the heat sink 4 than the side walls of the chip cavities, and therefore can be in good contact with the heat sink 4. In some embodiments, the heat dissipation surfaces 25 of the plurality of chips protrude from the side walls of the chip cavities by at least 0.4 mm.

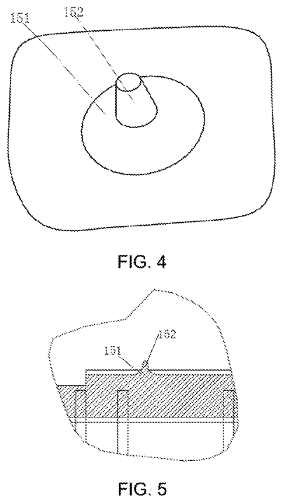

In some embodiments, as shown in FIG. 4 and FIG. 5, the plurality of support protrusions 15 and the bottom walls of the chip cavities 2 are integrally molded, for example, made of a plastic material and directly molded, for example, plastic such as nylon, resin, or the like. Therefore, the support protrusions 15 undergo plastic deformation after compression. Therefore, soldering may be performed after compressive force is released, and alternatively, soldering may be performed in the case that compressive force is maintained. Alternatively, the plurality of support protrusions 15 may also be clastic, so that soldering and fixing operations need to be completed in the case that the plurality of support protrusions 15 remain compressed. In some embodiments, the plurality of support protrusions 15 may substantially be in the shape of a hill before being compressed, i.e., the diameter thereof decreases as the height increases. In some embodiments, the plurality of support protrusions 15 have at least one tapered or truncated tapered segment before being compressed. In some embodiments, the plurality of support protrusions 15 may consist of two segments 151, 152, for example, two truncated conical segments. Specifically, the plurality of support protrusions 15 may include a first segment 151 having a first slope angle and a second segment 152 higher than the first segment 151 and having a second slope angle greater than the first slope angle. In some embodiments, the first slope angle is less than 45 degrees, and the second slope angle is greater than 60 degrees. Alternatively, the support protrusions 15 may have other suitable shapes. In some embodiments, the plurality of support protrusions 15 include at least four support protrusions 15 constituting a rectangular array. That is, at least four of the plurality of support protrusions 15 constitute a rectangular array. In some embodiments, the plurality of support protrusions include portions having diameters less than 1 mm, so as to be easily compressed and deform. For example, the maximum diameter of the second segment 152 is less than 1 mm.

In another aspect, according to an embodiment of the present invention, also provided is a manufacturing method of an electronic control unit, including: mounting a plurality of chips 2 in a plurality of chip cavities 10 of a chip support 1, each chip cavity 10 including a bottom wall 130, each chip including a support surface 24 close to the bottom wall and a heat dissipation surface 25 opposite the support surface, the bottom wall 130 of the chip cavity including a plurality of support protrusions 15, the chip 2 including a terminal 21, 22, 23, and the terminal 21, 22, 23 passing through a through hole 11, 12, 13 on the bottom wall 130 of the chip cavity and extending to a back side of the chip support 2; fixing the chip support 1, and performing compression from the heat dissipation surfaces 25 of the plurality of chips, so that the plurality of support protrusions 15 in each chip cavity deform, and the heat dissipation surfaces 25 of the plurality of chips are flush with each other; and soldering, on the back side of the chip support 2, the terminals 21, 22, 23 of the plurality of chips to a circuit board 3. In some embodiments, the method further includes: causing the heat dissipation surfaces 25 of the plurality of chips to abut and thermally contact a heat sink 4, and fixedly connecting, around the plurality of chip cavities, the chip support 2 to the heat sink 4 by means of bolts 5.

The electronic control unit according to the embodiments of the present invention can be used in a variety of electronic components of vehicles, such as an electric compressor.

The specific embodiments described above in the present application are merely intended to more clearly describe the principles of the present application, wherein components are clearly shown or described to make the principles of the present invention more comprehensible. Those skilled in the art can easily make various modifications or changes to the present application without departing from the scope of the present application. Therefore, it should be understood that these modifications or changes should all fall within the scope of patent protection of the present application.

1. An electronic control unit comprising:
a chip support (1), comprising a plurality of chip cavities (10), each of the chip cavities comprising a bottom wall (130);
chips (2) arranged in the chip cavities (10), each chip (2) comprising: a support surface (24) close to the bottom wall (130) and a heat dissipation surface (25) opposite the support surface (24), wherein the bottom wall (130) of the chip cavity is provided with a plurality of support protrusions (15), and in the case that the electronic control unit is completely assembled, the plurality of support protrusions (15) are compressed and deform; and
a heat sink (4), abutting and thermally contacting the heat dissipation surfaces (25) of the plurality of chips (2).

2. The electronic control unit according to claim 1, further comprising a circuit board (3) on a back side of the chip support (1), the bottom wall (130) of the chip cavity comprising one or more through holes (11, 12, 13), terminals (21, 22, 23) of the chip passing through corresponding through holes (11, 12, 13) and extending to the back side of the chip support (1), and the terminals (21, 22, 23) of the plurality of chips being soldered to the circuit board (3) in the case that the plurality of support protrusions (15) of the plurality of chip cavities are compressed and deform, so that the heat dissipation surfaces (25) of the chips (2) are flush with each other.

3. The electronic control unit according to claim 1, wherein the plurality of support protrusions (15) and the bottom walls (130) of the chip cavities are integrally molded, optionally, at least one tapered or truncated tapered segment being comprised before the plurality of support protrusions (15) are compressed, optionally, the plurality of support protrusions (15) comprising a first segment (151) having a first slope angle and a second segment (152) higher than the first segment (151) and having a second slope angle greater than the first slope angle, and optionally, the first slope angle being less than 45 degrees, and the second slope angle being greater than 60 degrees.

4. The electronic control unit according to claim 1, wherein the plurality of support protrusions (15) comprises four support protrusions constituting a rectangular array, and optionally, the plurality of support protrusions comprises portions having diameters less than 1 mm.

5. The electronic control unit according to claim 1, wherein the chip support is fastened to the heat sink (4) by means of a plurality of bolts (5) provided around the chip cavities, and optionally, an electrically insulating and thermally conductive film (41) is provided between the heat dissipation surfaces (25) of the plurality of chips (2) and the heat sink (4).

6. The electronic control unit according to claim 1, wherein in the case that the plurality of support protrusions (15) are compressed and deform, the heat dissipation surfaces (25) of the plurality of chips protrude from side walls (140) of the chip cavities, and optionally, the heat dissipation surfaces (25) of the plurality of chips protrude from the side walls (140) of the chip cavities by at least 0.4 mm.

7. The electronic control unit according to claim 1, wherein each of the chip cavities is in the shape of a flat rectangle, and comprises a support region (110) and a connecting region (120) on a side of the support region (110), the connecting region (120) being provided with the through hole (11, 12, 13) through which the terminal of the chip passes, and in the support region (110), the support protrusion (15) being provided at each of four corners of the bottom wall, and a middle portion of the bottom wall being provided a position-limiting protruding portion (16) to mate with a notch (20) of the chip, so as to limit the position of the chip in the chip cavity.

8. An electric compressor, characterized by comprising:
a compressor body; and
the electronic control unit according to claim 1, integrated on the compressor body.

9. A manufacturing method of an electronic control unit, characterized by comprising:
mounting a plurality of chips (2) in a plurality of chip cavities (10) of a chip support (1), each of the chip cavities (10) comprising a bottom wall (130), each chip comprising a support surface (24) close to the bottom wall (130) and a heat dissipation surface (25) opposite the support surface (24), the bottom wall (130) of the chip cavity comprising a plurality of support protrusions (15), the chip comprising a terminal (21, 22, 23), and the terminal (21, 22, 23) passing through a through hole (11, 12, 13) on the bottom wall of the chip cavity and extending to a back side of the chip support;
compressing, from the heat dissipation surfaces (25) of the plurality of chips, the plurality of chips towards the chip support by means of a flat indenter, so that the plurality of support protrusions in each of the chip cavities deform; and
soldering, on the back side of the chip support (1), the terminals (21, 22, 23) of the plurality of chips to a circuit board (3).

10. The manufacturing method of an electronic control unit according to claim 9, further comprising:
causing the heat dissipation surfaces (25) of the plurality of chips to abut and thermally contact a heat sink (4); and
fixedly connecting, around the plurality of chip cavities, the chip support (1) to the heat sink (4) by means of bolts (5).
